(19) United States
(12) Patent Application Publication
(10) Pub. No.: US 2026/0324128 A1
(43) Pub. Date: Oct. 15, 2026

(54) SENSOR PACKAGE STRUCTURE AND MANUFACTURING METHOD THEREOF

(71) Applicant: LITE-ON TECHNOLOGY CORPORATION, TAIPEI CITY (TW)

(72) Inventors: YUAN-JU CHENG, Kaohsiung City (TW); I-CHEN CHIEN, Keelung City (TW); HAN-HSING PENG, New Taipei City (TW)

(21) Appl. No.: 19/645,317

(22) Filed: Apr. 13, 2026

Related U.S. Application Data
(60) Provisional application No. 63/788,158, filed on Apr. 14, 2025.

(30) Foreign Application Priority Data
Apr. 8, 2026 (CN) 202610454065.6

(51) Int. Cl. H10F 77/40; H10F 30/225; H10F 39/90; H10F 77/50; H10H 20/853; H10H 20/855; H10H 29/20

(52) U.S. Cl. CPC H10F 77/407; H10F 30/225; H10F 39/90; H10F 77/50; H10H 20/853; H10H 20/855; H10H 29/20

(57) ABSTRACT

A sensor package structure and a manufacturing method thereof. The sensor package structure includes a substrate, a light emitter, a light receiver, two transparent bodies, and an encapsulant formed on the substrate. The light emitter and the light receiver are spaced apart from each other and are mounted on the substrate. The light emitter has at least one light-emitting region, and the light receiver has at least one light-receiving region. The two transparent bodies cover the at least one light-emitting region and the at least one light-receiving region, and respectively define a light-emitting surface and a light-incident surface. The light emitter, the light receiver, and the two transparent bodies are embedded in the encapsulant, and the light-emitting surface and the light-incident surface of the two transparent bodies are exposed from a top surface of the encapsulant.

### CROSS-REFERENCE TO RELATED PATENT APPLICATION

This application claims the benefit of priority to Patent Application No. 202610454065.6, filed on Apr. 8, 2026, in the People’s Republic of China. The entire content of the above identified application is incorporated herein by reference.

This application claims the benefit of priority to the U.S. Provisional Patent Application Ser. No. 63/788,158, filed on Apr. 14, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure and a manufacturing method thereof.

### BACKGROUND OF THE DISCLOSURE

In a conventional sensor package structure, a light-blocking member is integrated into a housing, and then the housing is provided for an assembling process. However, the assembly process of conventional sensor package structures often leads to concerns about light leakage from the light-blocking member.

### SUMMARY OF THE DISCLOSURE

In response to the above-referenced technical inadequacies, the present disclosure provides a sensor package structure and a manufacturing method thereof for effectively improving on the issues associated with conventional sensor package structures.

In order to solve the above-mentioned problems, one of the technical aspects adopted by the present disclosure is to provide a sensor package structure. The sensor package structure includes a substrate, a light emitter, a light receiver, a first transparent body, a second transparent body, and an encapsulant. The light emitter is assembled to the substrate and has at least one light-emitting region. The light receiver is assembled to the substrate and is spaced apart from the light emitter. The light receiver has at least one light-receiving region. The first transparent body covers the at least one light-emitting region and defines a light-emitting surface. The second transparent body covers the at least one light-receiving region and defines a light-incident surface. The encapsulant is formed on the substrate. The light emitter, the light receiver, the first transparent body, and the second transparent body are embedded in the encapsulant. The light-emitting surface of the first transparent body and the light-incident surface of the second transparent body are exposed from a top surface of the encapsulant. An area of the light-emitting surface is less than an area of the at least one light-emitting region corresponding thereto. An area of the light-incident surface is less than an area of the at least one light-receiving region corresponding thereto.

In order to solve the above-mentioned problems, another one of the technical aspects adopted by the present disclosure is to provide a manufacturing method of a sensor package structure, which is configured to manufacture the above sensor package structure.

In summary, the sensor package structure and the manufacturing method thereof provided by the present disclosure can achieve effective light-shielding functions through cooperation of components of the sensor package structure, thereby avoiding occurrence of light leakage, and further improving production efficiency, overall performance, and reliability of the sensor package structure.

Therefore, any one of the socket terminal, the conductive terminal set, and the power transmission assembly of the present disclosure is provided with the structural configuration of the insertion slot and the at least one communication slot relative to the limiting member so as to enable the at least one swing arm to effectively limit the plug terminal, thereby effectively improving the docking stability between the socket terminal and the plug terminal to ensure the power transmission quality of the conductive terminal set.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a schematic cross-sectional view taken along line II-II of FIG. 1;

FIG. 3 is a schematic top view of FIG. 1;

FIG. 4 is a schematic cross-sectional view showing a chip mounting step of a manufacturing method of the sensor package structure according to the first embodiment of the present disclosure;

FIG. 5 is a schematic top view showing the chip mounting step according to the first embodiment of the present disclosure;

FIG. 6 is a schematic cross-sectional view showing a shielding step of the manufacturing method according to the first embodiment of the present disclosure;

FIG. 7 is a schematic cross-sectional view showing a blocking step of the manufacturing method according to the first embodiment of the present disclosure;

FIG. 8 is a schematic top view showing the blocking step of the manufacturing method according to the first embodiment of the present disclosure;

FIGS. 9 and 10 are schematic cross-sectional views showing a transparent body forming step of the manufacturing method according to the first embodiment of the present disclosure;

FIG. 11 is a schematic top view showing the transparent body forming step of the manufacturing method according to the first embodiment of the present disclosure;

FIG. 12 is a schematic cross-sectional view showing an encapsulation step of the manufacturing method according to the first embodiment of the present disclosure;

FIG. 13 is a schematic cross-sectional view showing a grinding step of the manufacturing method according to the first embodiment of the present disclosure;

FIG. 14 is a schematic perspective view of the sensor package structure according to a second embodiment of the present disclosure;

FIG. 15 is a schematic cross-sectional view taken along line XV-XV of FIG. 14;

FIG. 16 is a schematic top view of FIG. 14;

FIG. 17 is a schematic top view of FIG. 14 showing the sensor package structure in another configuration;

FIG. 18 is a schematic cross-sectional view showing the chip mounting step according to a second embodiment of the present disclosure;

FIG. 19 is a schematic cross-sectional view showing the transparent body forming step according to the second embodiment of the present disclosure;

FIG. 20 is a schematic top view showing the transparent body forming step according to the second embodiment of the present disclosure;

FIG. 21 is a schematic cross-sectional view showing the encapsulation step according to the second embodiment of the present disclosure; and

FIG. 22 is a schematic cross-sectional view showing the grinding step according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

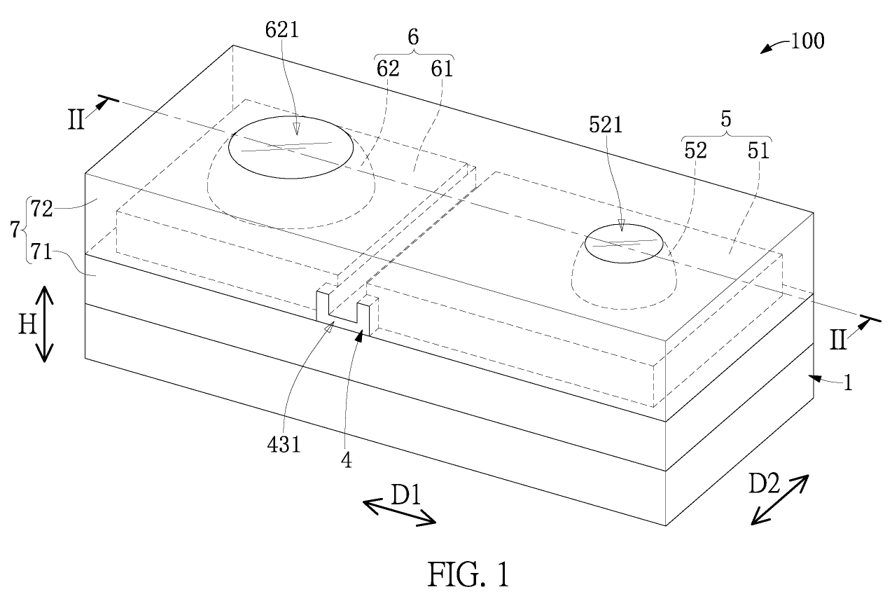

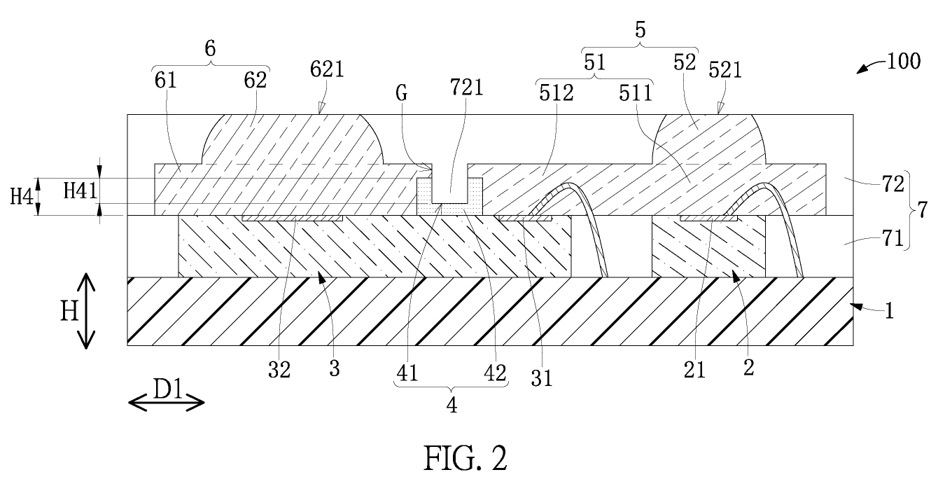

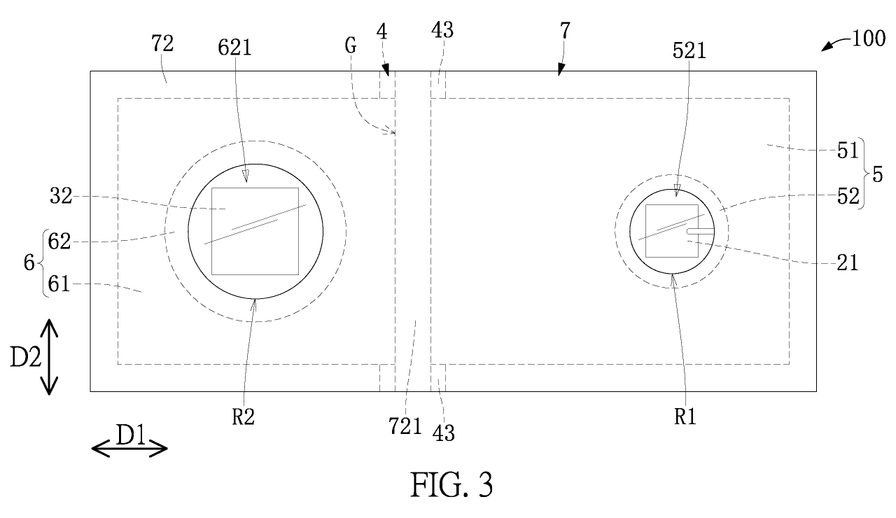

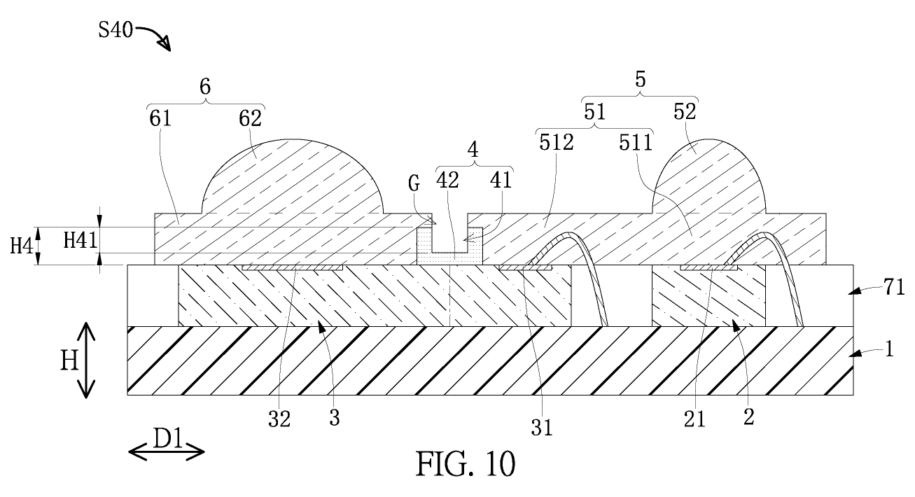

Reference is made to FIGS. 1-13, which show a first embodiment of the present disclosure. As shown in FIGS. 1-13, the present embodiment provides a sensor package structure 100, which includes a substrate 1, a light emitter 2 and a light receiver 3 both assembled to the substrate 1 and spaced apart from each other, a light-blocking wall 4 extending across the light receiver 3, a first transparent body 5 covering the light emitter 2, a second transparent body 6 covering the light receiver 3, and an encapsulant 7 that is formed on the substrate 1, but the present disclosure is not limited thereto. For example, in other embodiments of the present disclosure not shown in the drawings, the light-blocking wall 4 of the sensor package structure 100 can be omitted or can be replaced with other components according to practical requirements.

It should be noted that, for convenience of understanding the structures and connection relationships of the components of the sensor package structure 100 provided by the present embodiment, the sensor package structure 100 defines a first direction D1, second direction D2 perpendicular to the first direction D1, and a thickness direction H that is perpendicular to the first direction D1 and the second direction D2.

Furthermore, the encapsulant 7 in the present embodiment includes a light-shielding layer 71 and an encapsulation layer 72 that is connected to a periphery of the light-shielding layer 71. The light-shielding layer 71 and the encapsulation layer 72 preferably have light-shielding property, the light-shielding layer 71 and the encapsulation layer 72 can be formed in different steps and can be made of a same material or different materials according to practical requirements, and the present disclosure is not limited thereto.

In the present embodiment, the substrate 1 can be a ceramic substrate, a glass substrate, or a printed circuit board, and the light emitter 2 and the light receiver 3 are disposed on a same surface of the substrate 1 and are electrically coupled to the substrate 1 in a wire-bonding manner, but the present disclosure is not limited thereto. For example, in other embodiments of the present disclosure not shown in the drawings, at least one of the light emitter 2 and the light receiver 3 can be fixed and electrically coupled to the substrate 1 in a flip-chip bonding manner according to practical requirements.

Further, the light emitter 2 can be a light-emitting chip (e.g., VSCEL or LED) and has a light-emitting region 21 arranged on a top surface thereof, and the light receiver 3 can be a semiconductor optical sensor and has a first light-receiving region 31 and a second light-receiving region 32 both arranged on a top surface thereof. For example, the light receiver 3 can be a single-photon avalanche diode (SPAD) chip according to practical requirements, but the present disclosure is not limited thereto.

The light-emitting region 21 of the light emitter 2 is preferably coplanar with the first light-receiving region 31 and the second light-receiving region 32 of the light receiver 3. The light-emitting region 21, the first light-receiving region 31, and the second light-receiving region 32 in the present embodiment are substantially arranged in one row along the first direction D1, and the first light-receiving region 31 is located between the light-emitting region 21 and the second light-receiving region 32.

The light-shielding layer 71 is formed on the substrate 1, and a side edge of the light-shielding layer 71 is flush (or coplanar) with the side edge of the substrate 1. In the present embodiment, the light emitter 2 and the light receiver 3 are substantially embedded in the light-shielding layer 71, and the light-emitting region 21 of the light emitter 2 and the first light-receiving region 31 and the second light-receiving region 32 of the light receiver 3 are exposed from the light-shielding layer 71. In other words, a top surface of the light-shielding layer 71 is substantially flush (or coplanar) with the top surface of the light emitter 2 and the top surface of the light receiver 3, thereby jointly forming a flat surface.

The first transparent body 5 covers the light-emitting region 21 and defines a light-emitting surface 521 that corresponds in position to the light-emitting region 21 along the thickness direction H, and an area of the light-emitting surface 521 is less than an area of the light-emitting region 21. In the present embodiment, the first transparent body 5 is integrally formed as a single one-piece structure, and has a first base 51 and a first optical portion 52 that is formed on the first base 51. The first base 51 is substantially sheet-shaped and covers the light-emitting region 21 and the first light-receiving region 31, and a side edge of the first base 51 is arranged at an inner side of the side edge of the light-shielding layer 71. The first base 51 includes a main segment 511 and an extending segment 512 that extends from the main segment 511 along the first direction D1. The main segment 511 is connected to the first optical portion 52 and covers the light-emitting region 21, and the extending segment 512 extends across the light emitter 2 and the light receiver 3 and covers the first light-receiving region 31.

Furthermore, the first optical portion 52 corresponds in position to the light-emitting region 21 along the thickness direction H, and the first optical portion 52 tapers in a direction away from the substrate 1 (e.g., the first optical portion 52 being substantially a spherical zone or a spherical segment), and the light-emitting surface 521 is arranged on a surface of the first optical portion 52 away from the substrate 1. Specifically, the first projection region R1 defined by orthogonally projecting the light-emitting surface 521 onto the light emitter 2 surrounds the light-emitting region 21, and an area of the first projection region R1 is within a range from 35% to 200% of an area of the light-emitting region 21, but the present disclosure is not limited thereto.

The second transparent body 6 covers the second light-receiving region 32 and defines a light-incident surface 621 that corresponds in position to the second light-receiving region 32 along the thickness direction H. The light-incident surface 621 is preferably coplanar with the light-emitting surface 521, and an area of the light-incident surface 621 is less than an area of the corresponding second light-receiving region 32, but the present disclosure is not limited thereto. In the present embodiment, the second transparent body 6 is integrally formed as a single one-piece structure, and has a second base 61 and a second optical portion 62 that is formed on the second base 61. The second base 61 is substantially sheet-shaped and covers the two light-receiving regions 33, and a side edge of the second base 61 is arranged at an inner side of the side edge of the light-shielding layer 71.

Furthermore, the second optical portion 62 corresponds in position to the second light-receiving region 32 along the thickness direction H, and the second optical portion 62 tapers in a direction away from the substrate 1 (e.g., the second optical portion 62 being substantially a spherical zone or aspherical segment), and the light-incident surface 621 is arranged on a surface of the second optical portion 62 away from the substrate 1. Specifically, the second projection region R2 defined by orthogonally projecting the light-incident surface 621 onto the light receiver 3 surrounds the second light-receiving region 32, and an area of the second projection region R2 is within a range from 35% to 200% of an area of the light-incident surface 621 (e.g., preferably 8% to 80%), but the present disclosure is not limited thereto.

The light-blocking wall 4 in the present embodiment is an elongated structure parallel to the second direction D2, and a thickness H4 of the light-blocking wall 4 is preferably not greater than a thickness of the first base 51 and is not greater than a thickness of the second base 61. The light-blocking wall 4 has a groove 41 recessed from a top side thereof, and a depth H41 of the groove 41 is preferably greater than 30% of the thickness H4 of the light-blocking wall 4, but the present disclosure is not limited thereto. Furthermore, the light-blocking wall 4 extends across the light receiver 3 along the second direction D2 to isolate (or separate) the first light-receiving region 31 and the second light-receiving region 32 from each other. In other words, the light-blocking wall 4 separates the first base 51 of the first transparent body 5 from the second base 61 of the second transparent body 6.

The encapsulation layer 72 is formed on the light-shielding layer 71 (e.g., the encapsulation layer 72 connected to a periphery of the light-shielding layer 71), the light-blocking wall 4, the first transparent body 5, and the second transparent body 6 are embedded in the encapsulation layer 72, and the light-emitting surface 521 and the light-incident surface 621 are exposed from the encapsulation layer 72. In other words, the light emitter 2, the light receiver 3, the first transparent body 5, and the second transparent body 6 are embedded in the encapsulant 7, and the light-emitting surface 521 of the first transparent body 5 and the light-incident surface 621 of the second transparent body 6 are exposed from a top surface of the encapsulant 7.

Further, the first transparent body 5 and the second transparent body 6 are spaced apart from each other along the first direction D1 by a gap G that corresponds in position to the groove 41 of the light-blocking wall 4 along the thickness direction H. Furthermore, the encapsulant 7 (e.g., the encapsulation layer 72) has a separating portion 721, and the groove 41 and the gap G are filled by the separating portion 721. In other words, the separating portion 721 is connected to the light-blocking wall 4, and the light-blocking wall 4 and the separating portion 721 separate the first transparent body 5 and the second transparent body 6 from each other.

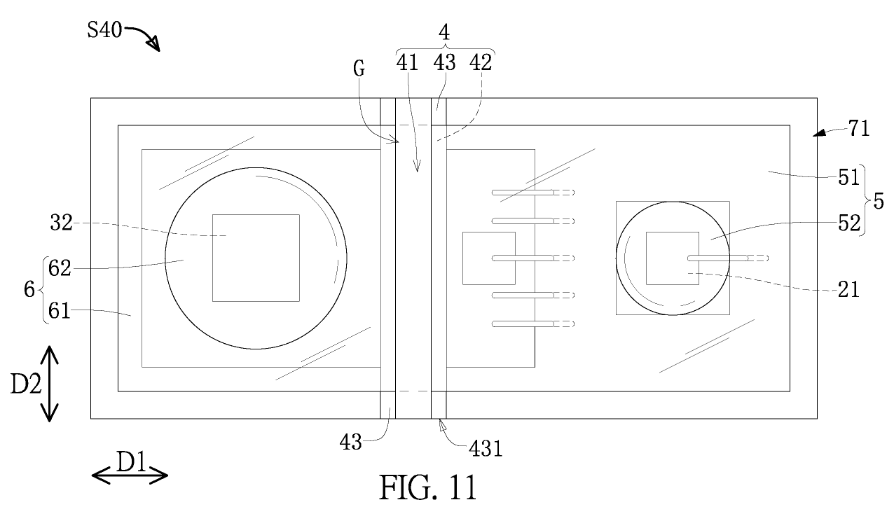

In addition, the light-blocking wall 4 in the present embodiment has a separating segment 42 and two embedded segments 43 that are respectively connected to two ends of the separating segment 42 as shown in FIG. 11. The separating segment 42 extends across the light receiver 3 to separate the first light-receiving region 31 and the second light-receiving region 32 from each other. Furthermore, the two embedded segments 43 are embedded in-between the light-shielding layer 71 and the encapsulation layer 72, and an end 431 of each of the two embedded segments 43 is flush (or coplanar) with an adjacent surface of the encapsulant 7. In other words, the end 431 of each of the two embedded segments 43 is exposed from the encapsulant 7, but the present disclosure is not limited thereto.

Accordingly, the sensor package structure 100 provided by the present embodiment can achieve effective light-shielding function through cooperation of the components of the sensor package structure 100, thereby avoiding occurrence of light leakage, and further improving production efficiency, overall performance, and reliability of the sensor package structure 100.

The above description describes the structure of the sensor package structure 100, and the following description discloses a manufacturing method of a sensor package structure. The sensor package structure 100 in the present embodiment can be manufactured by implementing the manufacturing method, so the relevant content of the manufacturing method can refer to the above description of the sensor package structure 100, but the present disclosure is not limited thereto. For example, in other embodiments of the present disclosure not shown in the drawings, the sensor package structure 100 can be manufactured by implementing other methods.

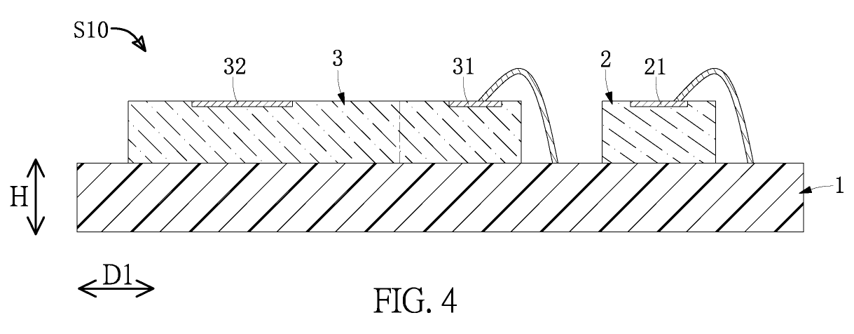

As shown in FIGS. 4-13, the manufacturing method in the present embodiment can sequentially include a chip mounting step S10, a shielding step S20, a blocking step S30, a transparent body forming step S40, an encapsulation step S50, and a grinding step S60, but the present disclosure is not limited thereto. For example, in other embodiments of the present disclosure not shown in the drawings, the shielding step S20 and the blocking step S30 can be omitted or can be replaced by other steps according to practical requirements.

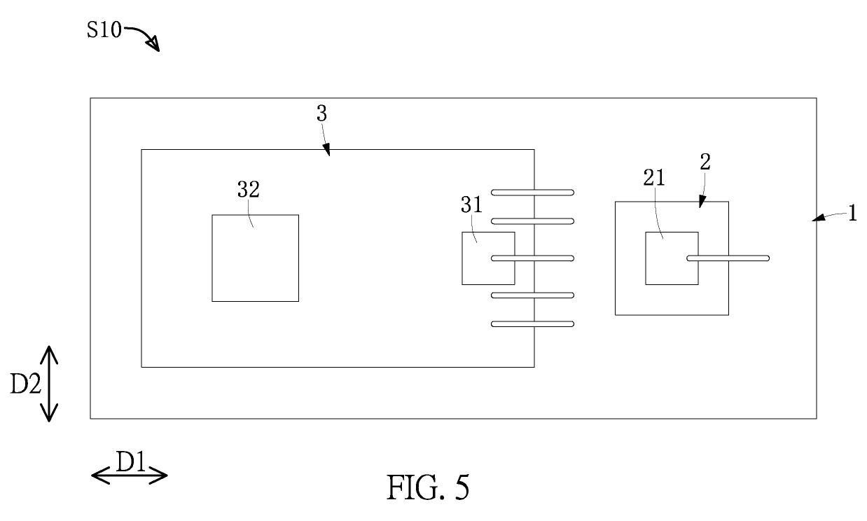

As shown in FIGS. 4 and 5, the chip mounting step S10 is implemented by mounting the light emitter 2 and the light receiver 3 onto the substrate 1. The light emitter 2 and the light receiver 3 are spaced apart from each other. The light emitter 2 has at least one light-emitting region 21, and the light receiver 3 has at least one light-receiving region 31, 32. In the present embodiment, a quantity of the at least one light-emitting region 21 included in the light emitter 2 is one, and a quantity of the at least one light-receiving region 31, 32 included in the light receiver 3 is two, which are respectively defined as a first light-receiving region 31 and a second light-receiving region 32.

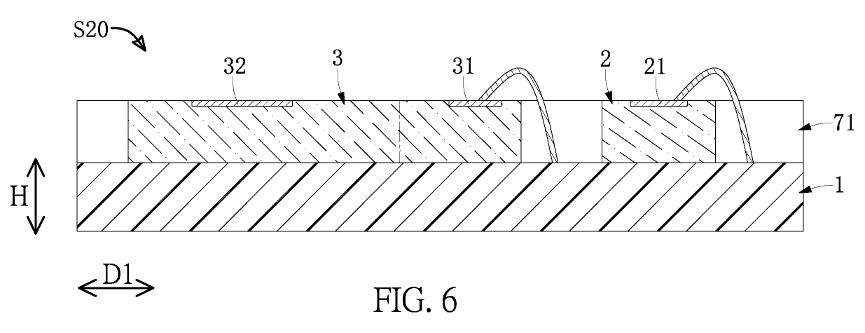

As shown in FIG. 6, the shielding step S20 is implemented by forming a light-shielding layer 71 on the substrate 1. The light emitter 2 and the light receiver 3 are embedded in the light-shielding layer 71, and the at least one light-emitting region 21, the first light-receiving region 31, and the second light-receiving region 32 are exposed from the light-shielding layer 71.

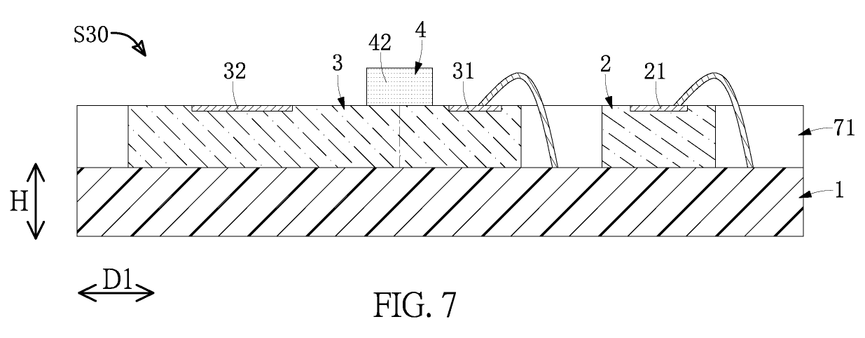

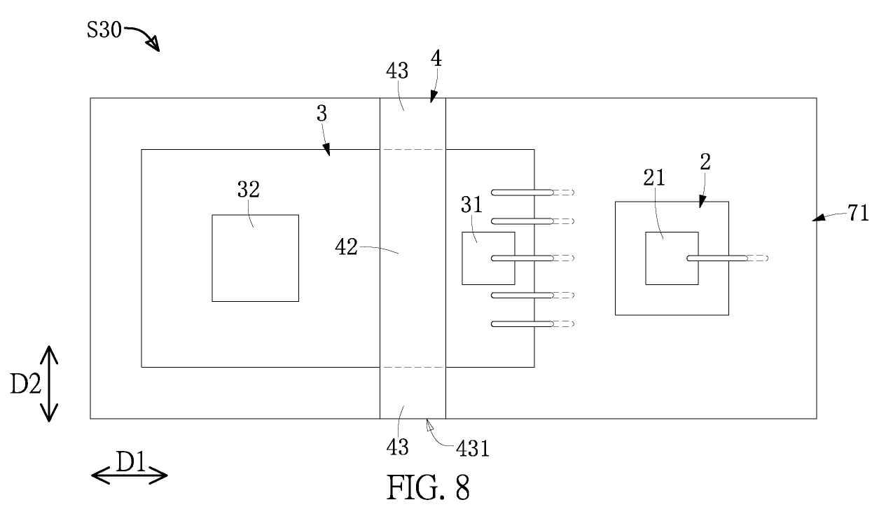

As shown in FIGS. 7 and 8, the blocking step S30 is implemented by forming a light-blocking wall 4 between the first light-receiving region 31 and the second light-receiving region 32. In the present embodiment, the light-blocking wall 4 is elongated and is parallel to the second direction D2, and the light-blocking wall 4 has a separating segment 42 extending across the light receiver 3 and two embedded segments 43 that are respectively connected to two ends of the separating segment 42 and that are located on the light-shielding layer 71.

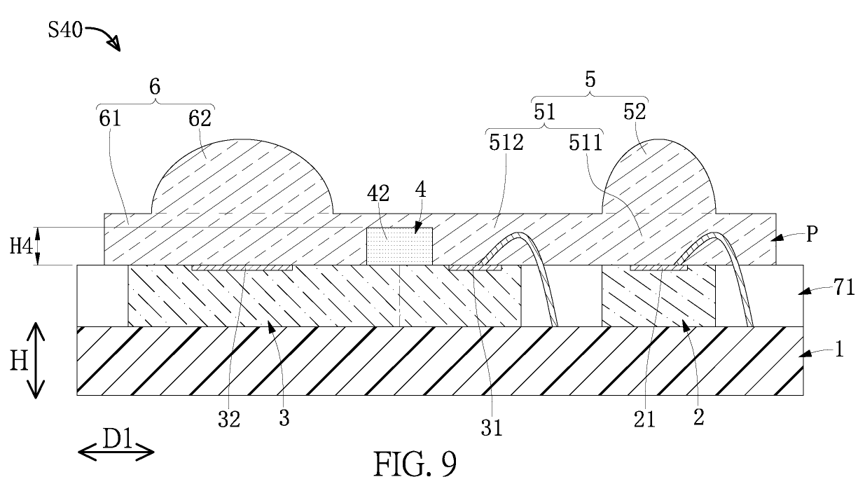

As shown in FIGS. 9-11, the transparent body forming step S40 is implemented by forming a transparent layer P to cover the at least one light-emitting region 21 and the at least one light-receiving region 31, 32. In the present embodiment, the transparent layer P is cut along the light-blocking wall 4 to form a gap G, such that the transparent layer P forms two transparent bodies 5 and 6 separated from each other through the gap G. Moreover, after the gap G is formed, the light-blocking wall 4 is subsequently cut to form a groove 41 having depth H41 that is greater than 30% of the thickness H4 of the light-blocking wall 4.

Further, one of the two transparent bodies 5 and 6 covers the at least one light-emitting region 21 and the first light-receiving region 31 and has a light-emitting surface 521, and is defined as a first transparent body 5. Another one of the two transparent bodies 5 and 6 covers the second light-receiving region 32 and has a light-incident surface 621 formed thereon, and is defined as a second transparent body 6.

Furthermore, the first transparent body 5 has a first optical portion 52 that tapers in a direction away from the substrate 1, and the light-emitting surface 521 is arranged on the first optical portion 52. The second transparent body 6 has a second optical portion 62 that tapers in a direction away from the substrate 1, and the light-incident surface 621 is arranged on the second optical portion 62.

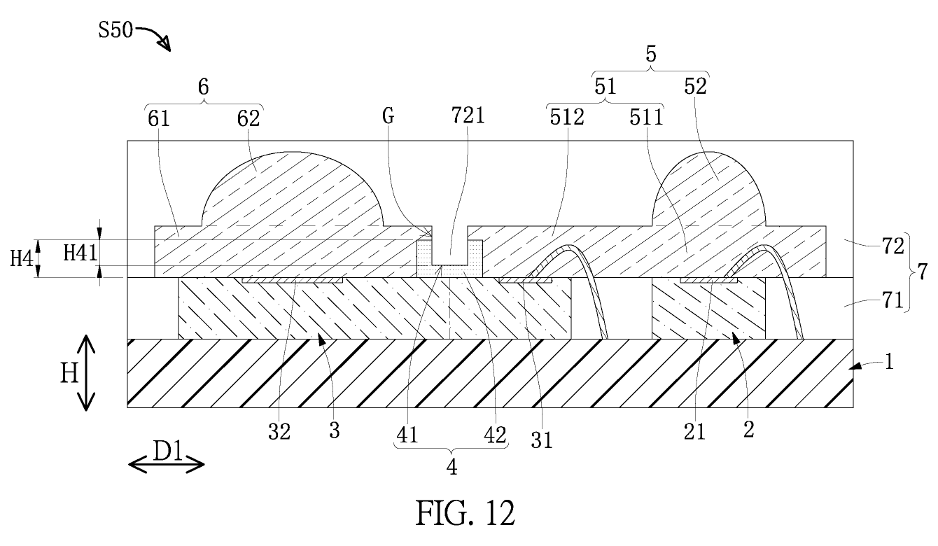

As shown in FIG. 12, the encapsulation step S50 is implemented by forming an encapsulation layer 72 to cover the two transparent bodies 5 and 6. In the present embodiment, the gap G and the groove 41 are filled by the encapsulation layer 72, and each of the two embedded segments 43 is embedded in-between the light-shielding layer 71 and the encapsulation layer 72.

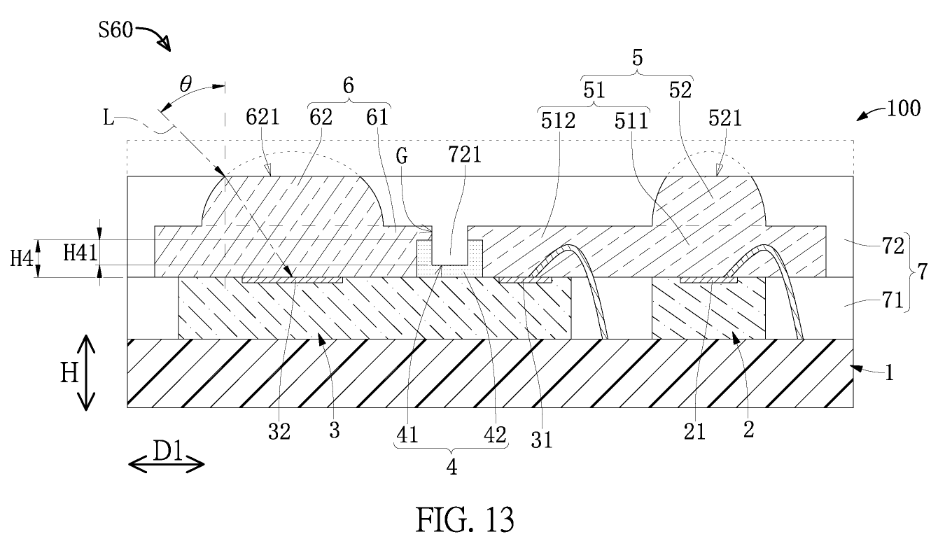

As shown in FIG. 13, the Grinding step S60 is implemented by grinding the encapsulation layer 72 from a surface thereof away from the substrate 1, until the two transparent bodies 5 and 6 are respectively ground to form the light-emitting surface 521 corresponding in position to the at least one light-emitting region 21 and the light-incident surface 621 corresponding in position to the at least one light-receiving region 31, 32 (e.g., the second light-receiving region 32).

In the present embodiment, the first projection region R1 defined by orthogonally projecting the light-emitting surface 521 onto the light emitter 2 surrounds the at least one light-emitting region 21, and an area of the first projection region R1 is within a range from 35% to 200% of an area of the light-emitting region 21. Furthermore, the second projection region R2 defined by orthogonally projecting the light-incident surface 621 onto the light receiver 3 surrounds the second light-receiving region 32, and an area of the second projection region R2 is within a range from 35% to 200% of an area of the second light-receiving region 32 (e.g., preferably 8% to 80%).

### Second Embodiment

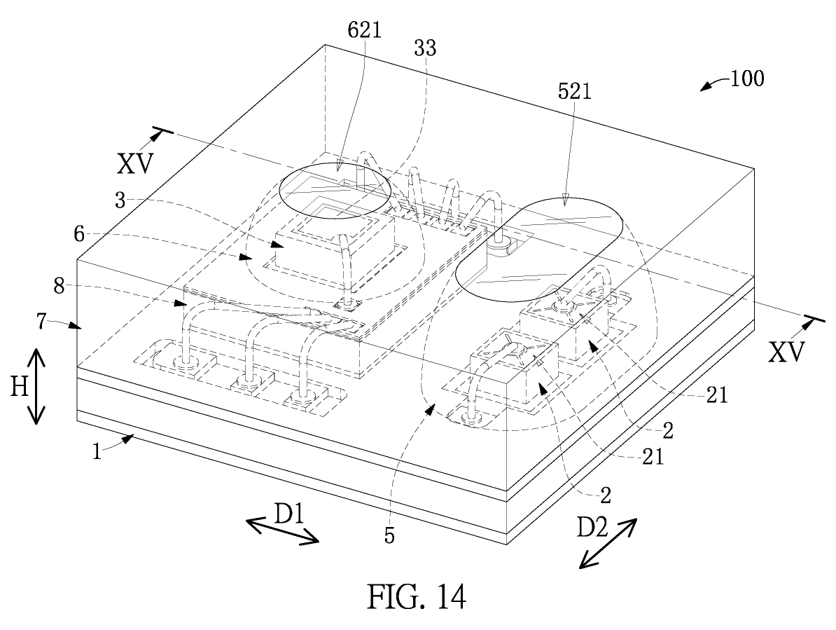

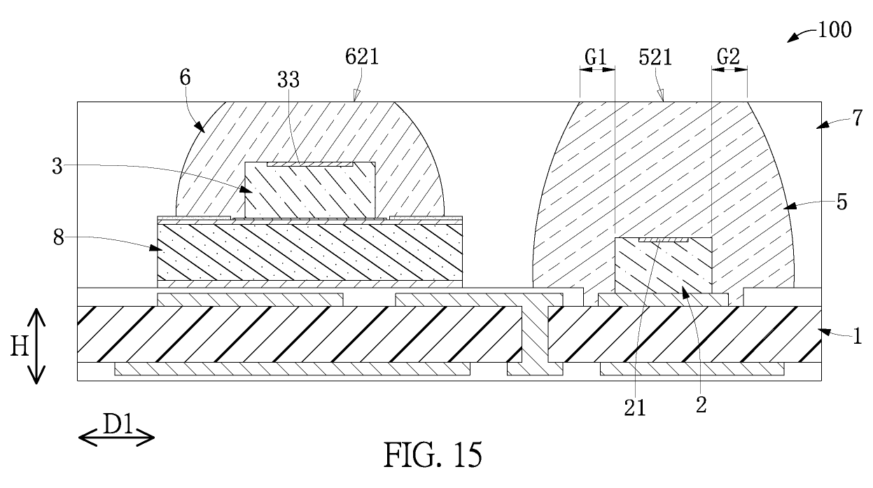

Reference is made to FIGS. 14-22, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, as shown in FIGS. 14-16, the sensor package structure 100 includes a substrate 1, a light emitter 2 and a light receiver 3 both assembled to the substrate 1 and spaced apart from each other, a first transparent body 5 covering the light emitter 2, a second transparent body 6 covering the light receiver 3, and an encapsulant 7 that is formed on the substrate 1. In other words, the sensor package structure 100 in the present embodiment does not have the light-blocking wall disclosed in the above first embodiment, and the encapsulant 7 in the present embodiment is integrally formed as a single one-piece structure (e.g., the encapsulant 7 made of a light-absorbing material that is directly and gaplessly bonded to the first transparent body 5 and the second transparent body 6).

In addition, the sensor package structure 100 in the present embodiment further includes a chip 8 disposed between the substrate 1 and the light receiver 3, and the light receiver 3 is electrically coupled to the chip 8, thereby being installed on (or assembled to) the substrate 1 through the chip 8. The light receiver 3 can be a photo detector (PD), and the chip 8 can be an application specific integrated circuit (ASIC) chip, but the present disclosure is not limited thereto. For example, in other embodiments of the present disclosure not shown in the drawings, the chip 8 of the sensor package structure 100 can omitted or can be replaced with other structures according to practical requirements (e.g., the chip 8 can be built into the light receiver 3).

In the present embodiment, the light emitter 2 includes two light-emitting regions 21 spaced apart from each other along the second direction D2, and the light emitter 2 defines a separating surface P located between the two light-emitting regions 21. In other words, the light emitter 2 can be divided into two blocks through the separating surface P.

Furthermore, the light receiver 3 has a light-receiving region 33, and a height of the light-receiving region 33 relative to the substrate 1 is greater than that of any one of the light-emitting regions 21. Moreover, a geometric center of the light-receiving region 33 is located on the separating surface P, and the two light-emitting regions 21 are arranged relative to the light-receiving region 33 at equal distances.

The light emitter 2 is embedded in the first transparent body 5, so the two light-emitting regions 21 are covered by the first transparent body 5. The first transparent body 5 (which can be regarded as an optical portion) tapers in a direction away from the substrate 1, and a light-emitting surface 521 is formed on a portion of the first transparent body 5 away from the substrate 1. Further, a first projection region R1 defined by orthogonally projecting the light-emitting surface 521 onto the light emitter 2 surrounds the two light-emitting regions 21, and an area of the first projection region R1 is within a range from 35% to 200% of an area of the two light-emitting regions 21, but the present disclosure is not limited thereto.

In other words, the first projection region R1 has a first side edge R11 adjacent to the light-receiving region 33 and a second side edge R12 that is away from the light-receiving region 33, and the two light-emitting regions 21 are adjacent to the first side edge R11. The first side edge R11 and the second side edge R12 are substantially parallel to the second direction D2.

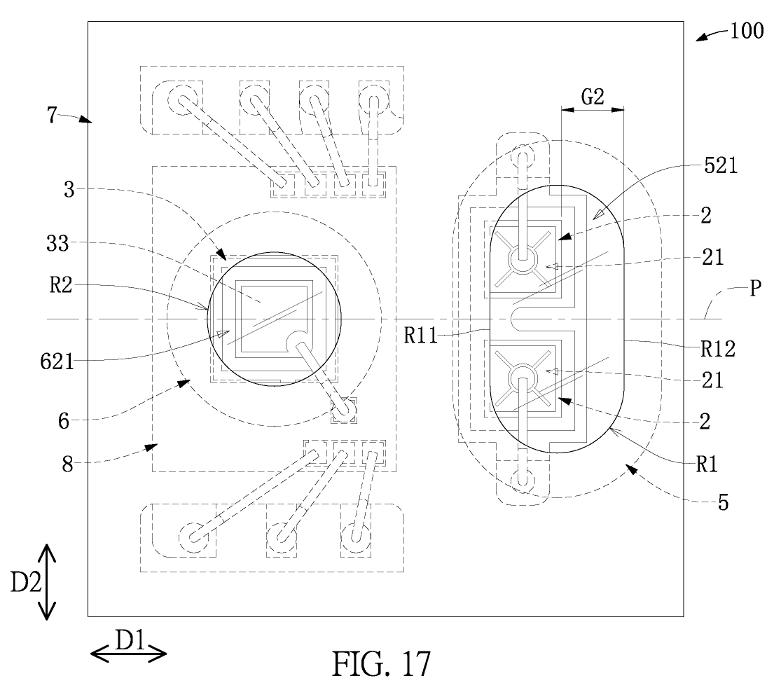

In the present embodiment, the two light-emitting regions 21 are spaced apart from the first side edge R11 along the first direction D1 by a first spacing G1, and the two light-emitting regions 21 are spaced apart from the second side edge R12 along the first direction D1 by a second spacing G2. The first spacing G1 is less than or equal to the second spacing G2, but the present disclosure is not limited thereto. For example, as shown in FIG. 17, the edges of the two light-emitting regions 21 adjacent to the light-receiving region 33 can be arranged along a straight direction (e.g., the second direction D2) and substantially overlap with the first side edge R11 of the first projection region R1; that is to say, the first spacing G1 in FIG. 17 is substantially equal to 0.

The second transparent body 6 is formed on the chip 8, and the light receiver 3 is embedded in the second transparent body 6. The second transparent body 6 (which can be regarded as an optical portion) tapers in a direction away from the substrate 1, and a light-incident surface 621 is formed on a portion of the second transparent body 6 away from the substrate 1.

Further, a second projection region R2 defined by orthogonally projecting the light-incident surface 621 onto the light receiver 3 surrounds the light-receiving region 33, and an area of the second projection region R2 is within a range from 35% to 200% of an area of the light-receiving region 33 (e.g., preferably 8% to 80%), but the present disclosure is not limited thereto.

In addition, the light emitter 2, the light receiver 3, the first transparent body 5, and the second transparent body 6 are embedded in the encapsulant 7, and the light-emitting surface 521 of the first transparent body 5 and the light-incident surface 621 of the second transparent body 6 are exposed from the top surface of the encapsulant 7.

The above description describes the structure of the sensor package structure 100, and the following description discloses a manufacturing method of a sensor package structure. The sensor package structure 100 in the present embodiment can be manufactured by implementing the manufacturing method, so the relevant content of the manufacturing method can refer to the above description of the sensor package structure 100, but the present disclosure is not limited thereto. For example, in other embodiments of the present disclosure not shown in the drawings, the sensor package structure 100 can be manufactured by implementing other methods.

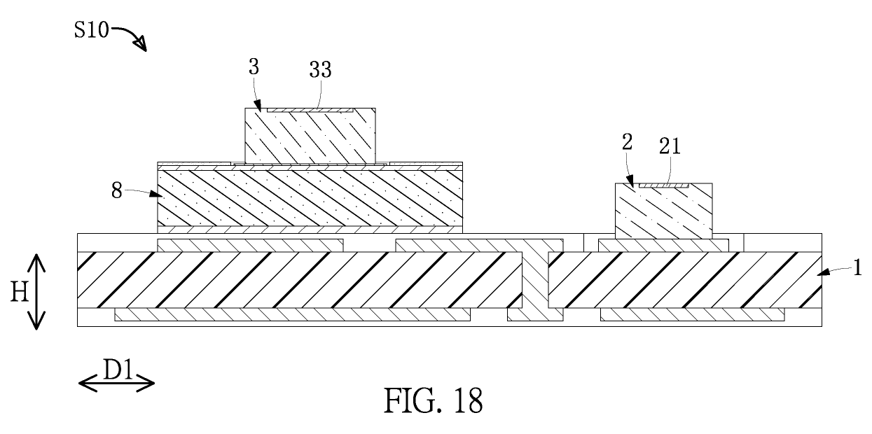

As shown in FIGS. 18-22, the manufacturing method in the present embodiment can sequentially include a chip mounting step S10, a transparent body forming step S40, an encapsulation step S50, and a grinding step S60, but the present disclosure is not limited thereto.

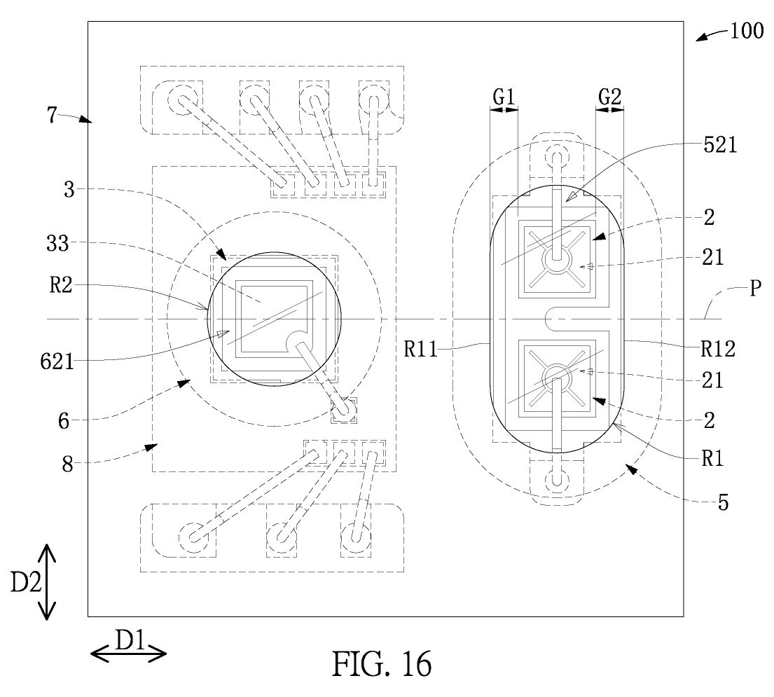

As shown in FIG. 18 and with reference to FIG. 16, the chip mounting step S10 is implemented by mounting a light emitter 2 and a light receiver 3 onto a substrate 1, and disposing a chip 8 between the substrate 1 and the light receiver 3. The light emitter 2 and the light receiver 3 are spaced apart from each other, the light emitter 2 has at least one light-emitting region 21, and the light receiver 3 has at least one light-receiving region 33.

In the present embodiment, a quantity of the at least one light-emitting region 21 included in the light emitter 2 is two, and a quantity of the at least one light-receiving region 33 included in the light receiver 3 is one. Furthermore, the two light-emitting regions 21 are spaced apart from each other, the light emitter 2 defines a separating surface P located between the two light-emitting regions 21, and a geometric center of the light-receiving region 33 is located on the separating surface P.

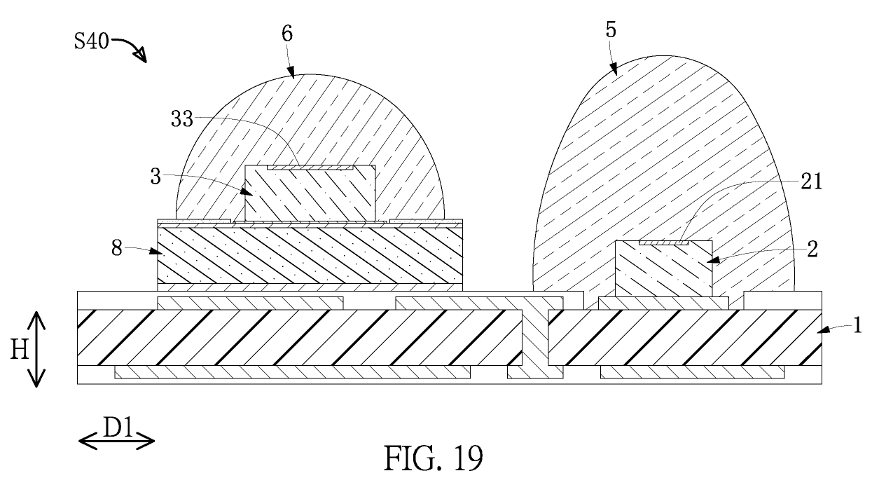

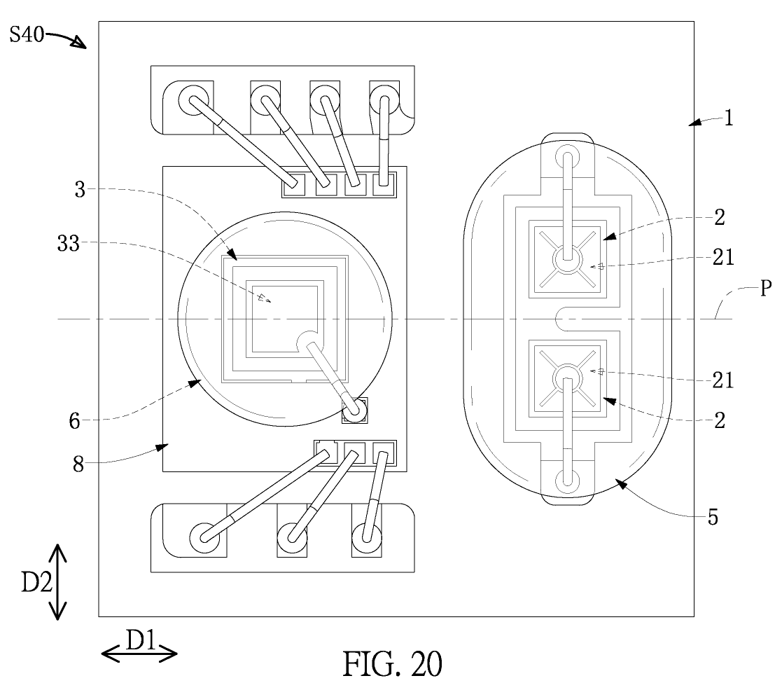

As shown in FIGS. 19 and 20, the transparent body forming step S40 is implemented by forming two transparent bodies 5 and 6 that respectively cover the at least one light-emitting region 21 and the at least one light-receiving region 33. The two transparent bodies 5 and 6 can be formed in a dispensing manner or a molding manner according to practical requirements. In the present embodiment, one of the two transparent bodies 5 and 6 covers the two light-emitting regions 21 and forms a light-emitting surface 521, and is defined as a first transparent body 5. Another one of the two transparent bodies 5 and 6 covers the light-receiving region 33 and forms a light-incident surface 621, and is defined as a second transparent body 6.

Further, the light emitter 2 is embedded in the first transparent body 5, the second transparent body 6 is formed on the chip 8, and the light receiver 3 is embedded in the second transparent body 6. The first transparent body 5 tapers in a direction away from the substrate 1, and the first transparent body 5 forms the light-emitting surface 521. The second transparent body 6 tapers in a direction away from the substrate 1, and the light-incident surface 621 is arranged on the second optical portion 62.

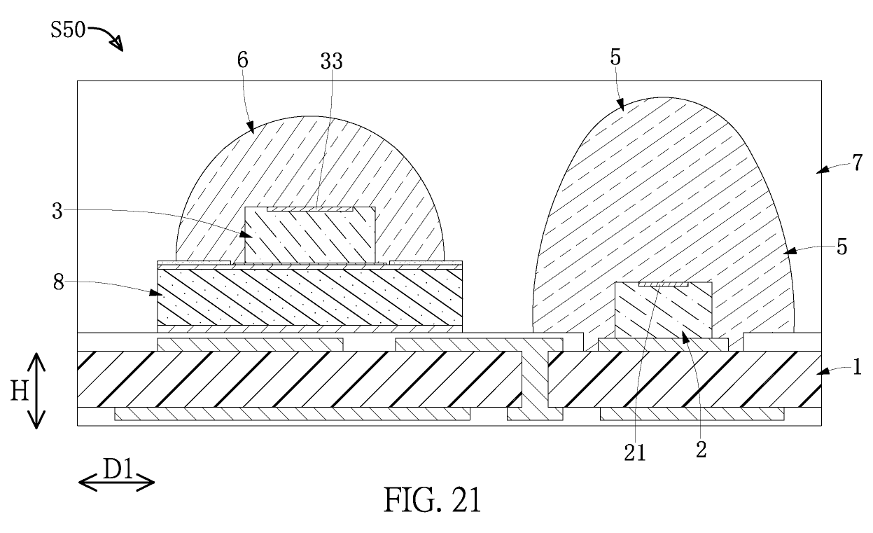

As shown in FIG. 21, the encapsulation step S50 is implemented by forming an encapsulant 7 that covers the two transparent bodies 5 and 6.

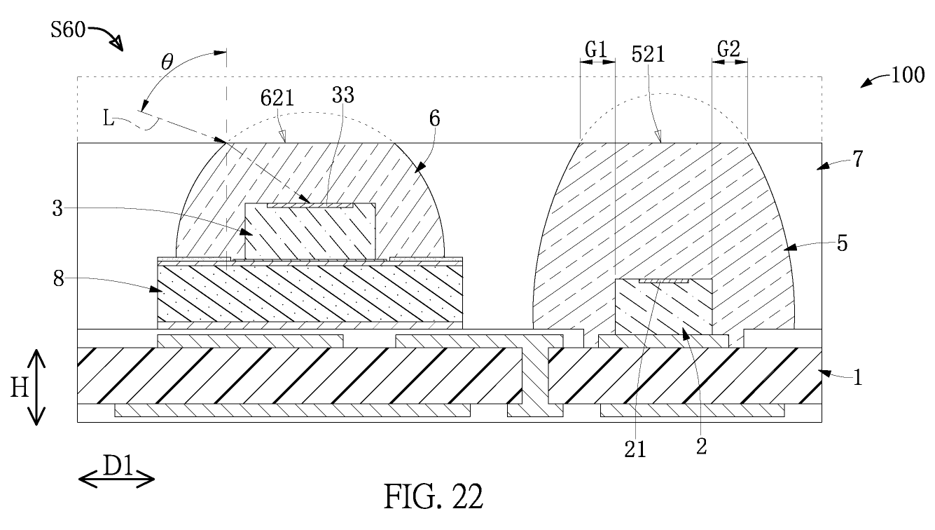

As shown in FIG. 22 and with reference to FIG. 16, the grinding step S60 is implemented by grinding the encapsulant 7 from a surface thereof away from the substrate 1, until the two transparent bodies 5 and 6 are ground to form the light-emitting surface 521 corresponding in position to the at least one light-emitting region 21 and the light-incident surface 621 corresponding in position to the at least one light-receiving region 33.

In the present embodiment, a first projection region R1 defined by orthogonally projecting the light-emitting surface 521 onto the light emitter 2 surrounds the two light-emitting regions 21, and an area of the first projection region R1 is within a range from 35% to 200% of an area of the two light-emitting regions 21. Furthermore, a second projection region R2 defined by orthogonally projecting the light-incident surface 621 onto the light receiver 3 surrounds the second light-receiving region 32, and an area of the second projection region R2 (which identical to an area of the light-incident surface 621) is within a range from 35% to 200% of an area of the light-receiving region 33 (e.g., preferably 8% to 80%).

Specifically, the first projection region R1 has a first side edge R11 adjacent to the light-receiving region 33 and a second side edge R12 that is away from the light-receiving region 33, and the two light-emitting regions 21 are arranged adjacent to the first side edge R11. The two light-emitting regions 21 are spaced apart from the first side edge R11 by a first spacing G1, the two light-emitting regions 21 are spaced apart from the second side edge R12 by a second spacing G2, and the first spacing G1 is less than or equal to the second spacing G2, but the present disclosure is not limited thereto.

For example, as shown in FIG. 17, the edges of the two light-emitting regions 21 adjacent to the light-receiving region 33 can be arranged along a straight direction (e.g., the second direction D2) and substantially overlap with the first side edge R11 of the first projection region R1; that is, the first spacing G1 shown in FIG. 17 is substantially equal to 0.

Furthermore, as shown in FIGS. 12 and 22, according to the grinding step S60 described in the first embodiment and the second embodiment, during the grinding process, the depth of grinding can be varied so that the light-incident surface 621 is used to limit light entering the light-receiving region 33, thereby causing the light to form an acceptance half-angle θ within a range from 10 degrees to 60 degrees relative to a normal direction of the light-incident surface 621 (i.e., the thickness direction H), but the present disclosure is not limited thereto.

In other words, the value of the acceptance half-angle θ is related to an area ratio between the second projection region R2 and the light-receiving region 33. For example, when the refractive index of the second transparent body 6 is 1.5 and the acceptance half-angle θ is 20 degrees, a refraction angle of the light is 13.18 degrees, and the area of the second projection region R2 can be calculated and obtained to be substantially 8% of the area of the light-receiving region 33 according to the above conditions. Furthermore, when the refractive index of the second transparent body 6 is 1.5 and the acceptance half-angle θ is 60 degrees, the refraction angle of the light is 35 degrees, and the area of the second projection region R2 can be calculated and obtained to be substantially 50% of the area of the light-receiving region 33 according to the above conditions.

### Technical Effects of Embodiments of the Present Disclosure

In summary, the sensor package structure and the manufacturing method thereof provided by the present disclosure can achieve optical isolation and signal quality enhancement through geometrically defined optical control and cooperation of components. By forming a light-emitting surface and a light-incident surface via a controlled grinding process and by limiting area ratios of the projection regions to the underlying light-emitting and light-receiving regions, light propagation is precisely confined. This configuration effectively suppresses stray light and optical crosstalk between the light emitter and the light receiver, thereby improving signal quality and measurement accuracy.

Furthermore, the acceptance half-angle of light entering the light-receiving region can be predictably controlled by the geometry of the light-incident surface without increasing structural complexity. Since optical isolation is primarily realized through surface geometry and quantified area relationships rather than thick light-blocking structures, thereby offering improved manufacturability, dimensional tolerance, and consistency across mass production, while enabling compact integration and stable optical performance.

The above-disclosed content is only preferred and feasible embodiments of the present disclosure, and does not limit the scope of patent rights of the present disclosure accordingly. Therefore, all equivalent technical changes made by using the specification and drawings of the present disclosure are included within the scope of patent rights of the present disclosure.

What is claimed is:

1. A sensor package structure, comprising:
a substrate;
a light emitter assembled to the substrate and having at least one light-emitting region;
a light receiver assembled to the substrate and spaced apart from the light emitter, wherein the light receiver has at least one light-receiving region;
a first transparent body covering the at least one light-emitting region and defining a light-emitting surface;
a second transparent body covering the at least one light-receiving region and defining a light-incident surface; and
an encapsulant formed on the substrate, wherein the light emitter, the light receiver, the first transparent body, and the second transparent body are embedded in the encapsulant;
wherein the light-emitting surface of the first transparent body and the light-incident surface of the second transparent body are exposed from a top surface of the encapsulant, an area of the light-emitting surface is less than an area of the at least one light-emitting region corresponding thereto, and an area of the light-incident surface is less than an area of the at least one light-receiving region corresponding thereto.

2. The sensor package structure according to claim 1, wherein a quantity of the at least one light-emitting region included in the light emitter is two, and the two light-emitting regions are spaced apart from each other, and wherein the light emitter defines a separating surface located between the two light-emitting regions, and a geometric center of the at least one light-receiving region is located on the separating surface.

3. The sensor package structure according to claim 2, further comprising a chip disposed between the substrate and the light receiver, wherein the second transparent body is formed on the chip and covers the light receiver.

4. The sensor package structure according to claim 2, wherein the two light-emitting regions are arranged relative to the at least one light-receiving region at equal distances.

5. The sensor package structure according to claim 2, wherein a first projection region defined by orthogonally projecting the light-emitting surface onto the light emitter surrounds the two light-emitting regions, wherein the first projection region has a first side edge adjacent to the light-receiving region and a second side edge that is away from the light-receiving region, and wherein the two light-emitting regions are arranged adjacent to the first side edge.

6. The sensor package structure according to claim 5 wherein the two light-emitting regions are spaced apart from the first side edge by a first spacing, and the two light-emitting regions are spaced apart from the second side edge by a second spacing, and wherein the first spacing is less than or equal to the second spacing.

7. The sensor package structure according to claim 1, wherein the second transparent body has a second optical portion that tapers in a direction away from the substrate, and the light-incident surface is arranged on the second optical portion.

8. The sensor package structure according to claim 7, wherein the first transparent body has a first optical portion that tapers in a direction away from the substrate, and the light-emitting surface is arranged on the first optical portion.

9. The sensor package structure according to claim 7, wherein the light-incident surface is configured to limit light entering the light-receiving region for enabling the light to have an acceptance half-angle that is within a range from 10 degrees to 60 degrees relative to a normal direction of the light-incident surface.

10. The sensor package structure according to claim 7, wherein a second projection region defined by orthogonally projecting the light-incident surface onto the light receiver surrounds the at least one light-receiving region, and wherein an area of the at least one second projection region is within a range from 8% to 80% of an area of the light-receiving region.

11. The sensor package structure according to claim 7, wherein the encapsulant is a light-absorbing adhesive material that is directly and gaplessly bonded to the first transparent body and the second transparent body.

12. The sensor package structure according to claim 1, wherein the encapsulant includes:
a light-shielding layer formed on the substrate, wherein the at least one light-emitting region and the at least one light-receiving region are exposed from the light-shielding layer; and
an encapsulation layer formed on the light-shielding layer, wherein the first transparent body and the second transparent body are embedded in the encapsulation layer, and the light-emitting surface and the light-incident surface are exposed from the encapsulation layer.

13. The sensor package structure according to claim 12, wherein the first transparent body includes an extending segment covering an additional light-receiving region different from the at least one light-receiving region covered by the second transparent body.

14. A manufacturing method of a sensor package structure, comprising:
a chip mounting step implemented by mounting a light emitter and a light receiver onto a substrate, wherein the light emitter and the light receiver are spaced apart from each other, the light emitter has a light-emitting region, and the light receiver has a first light-receiving region and a second light-receiving region;
a shielding step implemented by forming a light-shielding layer on the substrate, wherein the light emitter and the light receiver are embedded in the light-shielding layer, and the light-emitting region, the first light-receiving region, and the second light-receiving region are exposed from the light-shielding layer;
a blocking step implemented by forming a light-blocking wall between the first light-receiving region and the second light-receiving region;
a transparent body forming step implemented by forming a transparent layer that covers the light-emitting region, the first light-receiving region, and the second light-receiving region, and cutting the transparent layer along the light-blocking wall to form a gap, such that the transparent layer forms a first transparent body and a second transparent body that is separated from the first transparent body through the gap, wherein the first transparent body covers the light-emitting region and the first light-receiving region, and the second transparent body covers the second light-receiving region;
an encapsulation step implemented by forming an encapsulation layer that is filled in the gap and that covers the first transparent body and the second transparent body; and
a grinding step implemented by grinding the encapsulation layer from a surface thereof that is away from the substrate, until the first transparent body is ground to form a light-emitting surface corresponding in position to the light-emitting region, and the second transparent body is ground to form a light-incident surface corresponding in position to the second light-receiving region.

15. The manufacturing method according to claim 14, wherein the first transparent body has a first optical portion that tapers in a direction away from the substrate, and the light-emitting surface is arranged on the first optical portion, and wherein the second transparent body has a second optical portion that tapers in a direction away from the substrate, and the light-incident surface is arranged on the second optical portion.

16. A manufacturing method of a sensor package structure, comprising:
a chip mounting step implemented by mounting a light emitter and a light receiver onto a substrate, wherein the light emitter and the light receiver are spaced apart from each other, the light emitter has two light-emitting regions, and the light receiver has a light-receiving region;
a transparent body forming step implemented by forming a first transparent body that covers the two light-emitting regions and a second transparent body that covers the light-receiving region;
an encapsulation step implemented by forming an encapsulant on the substrate, wherein the encapsulant covers the first transparent body and the second transparent body; and
a grinding step implemented by grinding the encapsulant from a surface thereof that is away from the substrate, until the first transparent body is ground to form a light-emitting surface corresponding in position to the two light-emitting regions, and the second transparent body is ground to form a light-incident surface corresponding in position to the light-receiving region.

17. The manufacturing method according to claim 16, wherein, in the chip mounting step, a chip is mounted between the substrate and the light receiver, and wherein, in the transparent body forming step, the second transparent body is formed on the chip, the light receiver is embedded in the second transparent body, and the light emitter is embedded in the first transparent body.

18. The manufacturing method according to claim 17, wherein the two light-emitting regions are spaced apart from each other, the light emitter defines a separating surface that is located between the two light-emitting regions, and a center of the light-receiving region is located on the separating surface.

19. The manufacturing method according to claim 16, wherein, in the grinding step, a first projection region defined by orthogonally projecting the light-emitting surface onto the light emitter surrounds the two light-emitting regions, the first projection region has a first side edge adjacent to the at least one light-receiving region and a second side edge away from the at least one light-receiving region, and the two light-emitting regions are arranged adjacent to the first side edge.

20. The manufacturing method according to claim 16, wherein the first transparent body tapers in a direction away from the substrate, and the second transparent body tapers in a direction away from the substrate, and wherein, in the grinding step, a first projection region is defined by orthogonally projecting the light-emitting surface onto the light emitter, and a second projection region defined by orthogonally projecting the light-incident surface onto the light receiver has an area that is within a range from 8% to 80% of an area of the light-receiving region.
